(19) United States
(12) Patent Application Publication
(10) Pub. No.: US 2006/0124961 A1
(43) Pub. Date: Jun. 15, 2006

(54) Semiconductor substrate, manufacturing method thereof, and semiconductor device

(75) Inventors: Kiyofumi Sakaguchi, Tokyo (JP); Kazuya Notsu, Tokyo (JP); Kazutaka Momoi, Tokyo (JP); Nobuhiko Sato, Tokyo (JP)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 10/540,263

(22) PCT Filed: Dec. 14, 2004
(86) PCT No.: PCT/JP04/18981

§ 371 Date: Jun. 23, 2005

(30) Foreign Application Priority Data
Dec. 26, 2003 (JP) 2004-434019

(51) Int. Cl. H01L 31/0328

(52) U.S. Cl. 257/192; 257/616

(57) ABSTRACT

A separation layer is formed on a silicon substrate. An SiGe layer serving as a strain induction layer and a silicon layer serving as a strained semiconductor layer are formed sequentially on the separation layer to prepare a first substrate. The first substrate is bonded to a second substrate made of the same material as the silicon layer of the strained semiconductor layer. The structure is separated into two parts at the separation layer. When the residue of the separation layer and the SiGe layer are removed, and the surface is planarized by hydrogen annealing, an Si substrate having a strained silicon layer on the uppermost surface is obtained.

### TECHNICAL FIELD

The present invention relates to a semiconductor substrate, a manufacturing method thereof, and a semiconductor device.

### BACKGROUND ART

As a substrate to form a semiconductor device with a high speed and low power consumption, a substrate having a strained silicon layer has received a great deal of attention. A layer (SiGe layer) made of silicon (Si) and germanium (Ge) is grown on a silicon substrate, and a single-crystal silicon layer is grown on that layer. Accordingly, a strain is applied to the silicon layer, and a strained silicon layer is obtained. This strain occurs because the lattice constant of the SiGe layer is slightly larger than that of the single-crystal silicon layer. For example, U.S. Pat. No. 5,221,413 to AT&T describes a strained-Si/SiGe/Si substrate.

On the other hand, an SOI substrate having a buried oxide film in a silicon substrate has also received a great deal of attention and put to use as a substrate to form a semiconductor device with a high speed and low power consumption. A comprehensive report of a combined structure of strained-Si and an SOI (Silicon On Insulator) structure has also been made. This substrate is put into practical use to implement both the high-speed operation by strained-Si and low power consumption performance and higher operation speed of SOI (Shin-ichi Takagi, “Metal-Oxide-Semiconductor (MOS) device technologies using Si/SiGe heretointerfaces”, Oyo Buturi, vol. 72, no. 3, pp. 284-290, 2003). In this reference, the substrate is described in association with the structure of a “strained-Si/SiGe/Insulator/Si substrate”.

A “strained-Si/insulator/Si substrate” structure having no SiGe layer has also been reported (T. A. Langdo, et. al., Appl. Phys. Lett., vol. 82, no. 24, pp. 4256-4258 (2003)). In this method, after strained-Si/SiGe formed on a first substrate is transferred to an insulating substrate by hydrogen ion implantation, bonding, and separation, the SiGe layer is removed.

All the above-described techniques require further optimization in device and process design, as compared to current Si-LSI. The existence of SiGe is described even in the paper by T. A. Langdo, et. al. However, there still remain problems of the difference in dopant diffusion, metal contact formation, and Ge diffusion by annealing. In addition, a structure having an insulating layer has the same problems as in SOI because of the presence of the insulating layer, including the problem of heat accumulation by the device operation.

### DISCLOSURE OF INVENTION

The present invention has been made in consideration of the above situations, and has as its object to provide a new technique to form, e.g., an Si wafer having a strained-Si layer.

According to the first aspect of the present invention, there is provided a semiconductor substrate comprising, on the semiconductor substrate, a strained semiconductor layer which is made of the same material as the semiconductor substrate. The “semiconductor substrate” includes at least a single-crystal semiconductor substrate and polycrystalline semiconductor substrate and also includes a substrate having a polycrystalline semiconductor layer (including a microcrystalline semiconductor layer) formed on a semiconductor substrate.

According to the second aspect of the present invention, there is provided a method of manufacturing a semiconductor substrate of the present invention, comprising a first step of forming a strained semiconductor layer which is made of a first material on a semiconductor substrate which is made of a second material at least whose surface functions as a strain induction material to prepare a first substrate, a second step of bonding the strained semiconductor layer of the first substrate to a second substrate which is made of the first material, and a third step of removing a member on a side of the first substrate except the strained semiconductor layer and leaving the strained semiconductor layer on the second substrate.

According to the third aspect of the present invention, there is provided a semiconductor substrate manufactured by the above manufacturing method.

According to the fourth aspect of the present invention, there is provided a semiconductor device having a field effect transistor formed on the strain induction layer of the semiconductor substrate.

By the semiconductor substrate of the present invention, the channel mobility can be increased by the strain without changing the process developed by the convention Si-LSI technique.

Other features and advantages of the present invention will be apparent from the following description taken in conjunction with the accompanying drawings, in which like reference characters designate the same or similar parts throughout the figures thereof.

### BRIEF DESCRIPTION OF DRAWINGS

The accompanying drawings, which are incorporated in and constitute a part of the specification, illustrate embodiments of the invention and, together with the description, serve to explain the principles of the invention.

FIG. 1A is a view showing the layered structure of a first substrate according to Example 1 of the present invention, FIG. 1B is a view showing a bonding step according to Example 1 of the present invention, and FIG. 1C is a view showing a removal step according to Example 1 of the present invention;

FIG. 2A is a view showing the layered structure of a first substrate according to Example 2, FIG. 2B is a view showing a bonding step according to Example 2, FIG. 2C is a view showing a separation step according to Example 2, and FIG. 2D is a view showing a removal step according to Example 2;

FIG. 3A is a view showing the layered structure of a first substrate according to Example 3, FIG. 3B is a view showing a bonding step according to Example 3, FIG. 3C is a view showing a separation step according to Example 3, and FIG. 3D is a view showing a removal step according to Example 3;

FIG. 4A is a view showing a growing step according to Example 4, FIG. 4B is a view showing an anodizing step according to Example 4, FIG. 4C is a view showing the layered structure of a first substrate according to Example 4, FIG. 4D is a view showing a bonding step according to Example 4, FIG. 4E is a view showing a separation step according to Example 4, and FIG. 4F is a view showing a removal step according to Example 4;

FIG. 5A is a view showing a growing step according to Example 5, FIG. 5B is a view showing an anodizing step according to Example 5, FIG. 5C is a view showing the layered structure of a first substrate according to Example 5, FIG. 5D is a view showing a bonding step according to Example 5, FIG. 5E is a view showing a separation step according to Example 5, and FIG. 5F is a view showing a removal step according to Example 5;

FIG. 6A is a view showing an anodizing step according to Example 6, FIG. 6B is a view showing the layered structure of a first substrate according to Example 6, FIG. 6C is a view showing a bonding step according to Example 6, FIG. 6D is a view showing a separation step according to Example 6, and FIG. 6E is a view showing a removal step according to Example 6;

FIG. 7A to 7D are views showing a semiconductor substrate and a manufacturing method thereof; and

FIG. 8 is a schematic sectional view showing a state in which a layer (Si₁₋ₓGeₓ layer) containing germanium is formed as the pore sealing member of a porous surface layer.

### BEST MODE FOR CARRYING OUT THE INVENTION

The preferred embodiments of the present invention will be described below.

The preferred embodiments of the present invention are directed to a method of forming a strained semiconductor made of a first material on a semiconductor substrate made of a second material and includes the following embodiments.

### First Embodiment

A strain induction layer is formed on the surface of a semiconductor substrate made of a second material. A strained semiconductor layer made of a first material is formed on the strain induction layer to prepare a first substrate. A second substrate made of a first material is bonded to the first substrate. The semiconductor substrate made of the second material and the strain induction layer are removed. Accordingly, the strained semiconductor layer made of the first material can be formed on the second substrate made of the first material while being in contact with the second substrate.

As the first and second materials, silicon is typically used.

As the strain induction layer, a layer (Si₁₋ₓGeₓ layer) containing silicon and germanium is formed. A layer (preferably, a single-crystal silicon layer) almost made of silicon is formed on the Si₁₋ₓGeₓ layer as a strained semiconductor layer.

In the Si₁₋ₓGeₓ layer formed on the semiconductor substrate made of the second material, x preferably falls within the range of 0 to 0.5. More preferably, x is almost 0 on the surface of the semiconductor substrate and gradually changes. On the uppermost surface on which the strained semiconductor layer is formed, x is preferably 0.1 to 0.5. Lattice relaxation occurs at least on the uppermost surface so that the strain there is small.

The member on the first substrate side except the strained semiconductor layer can be removed by a mechanical removing method such as grinding or polishing. Alternatively, hydrogen ions may be implanted into the semiconductor substrate made of the second material or the strain induction layer before bonding, and after bonding, the members may be separated at the implantation interface.

The Si₁₋ₓGeₓ layer on the strained semiconductor layer is removed by polishing or chemical etching.

After the Si₁₋ₓGeₓ layer is removed, and only the strained semiconductor layer is left on the second substrate, surface planarization may be done. A manufacturing method according to this embodiment can further comprise a step of forming a circuit element by using the strained semiconductor layer as an active layer. For a device having such a circuit element, a high-speed operation can be implemented by the strained semiconductor layer.

### Second Embodiment

A separation layer is formed on the surface of a semiconductor substrate made of a second material. A strain induction layer is formed on the separation layer. In addition, a strained semiconductor layer made of a first material is formed on the strain induction layer to prepare a first substrate.

A second substrate made of a first material is bonded to the first substrate. The members are separated at the separation layer. After that, the remaining separation layer and strain induction layer are removed. Accordingly, the strained semiconductor layer made of the first material can be formed on the second substrate made of the first material while being in contact with the second substrate.

As the first and second materials, silicon is typically used. The separation layer can be formed typically by porosifying the surface of the semiconductor substrate (silicon substrate) made of the second material by anodizing. As another method, after the strain induction layer and strained semiconductor layer are formed, ions of, e.g., hydrogen are implanted to form the separation layer in the strain induction layer or the semiconductor substrate made of the second material.

As the strain induction layer, a layer (Si₁₋ₓGeₓ layer) containing germanium is formed. A layer (preferably, a single-crystal silicon layer) almost made of silicon is formed on the Si₁₋ₓGeₓ layer as a strained semiconductor layer.

In the Si₁₋ₓGeₓ layer formed on the separation layer, x preferably falls within the range of 0 to 0.5. More preferably, x is almost 0 on the surface of the separation layer and gradually changes. On the uppermost surface on which the strained semiconductor layer is formed, x is preferably 0.1 to 0.5. Lattice relaxation occurs at least on the uppermost surface so that the strain there is small.

When the separation layer is a porous layer, the separation step is executed by wedge insertion, tensile/shearing force application, liquid jet (e.g., water jet) injection, gas jet injection, or ultrasonic wave application. When the separation layer is formed by ion implantation, the separation step is done by annealing at 200° C. to 300° C. to 500° C. to 600° C.

The Si₁₋ₓGeₓ layer on the strained semiconductor layer is removed by polishing or chemical etching.

After the Si₁₋ₓGeₓ layer is removed, and only the strained semiconductor layer is left on the second substrate, surface planarization may be done.

A manufacturing; method according to this embodiment can further comprise a step of forming a circuit element by using the strained semiconductor layer as an active layer. For a device having such a circuit element, a high-speed operation can be implemented by the strained semiconductor layer.

### Third Embodiment

A separation layer is formed on the surface of a semiconductor substrate made of a second material. A strain induction layer is formed on the separation layer. In addition, a strained semiconductor layer made of a first material is formed on the strain induction layer to prepare a first substrate.

A second substrate made of a first material is bonded to the first substrate. The members are separated at the separation layer. After that, the remaining separation layer and strain induction layer are removed. Accordingly, the strained semiconductor layer made of the first material can be formed on the second substrate made of the first material while being in contact with the second substrate.

As the first and second materials, silicon is typically used.

The separation layer can be formed typically by porosifying the surface of the semiconductor substrate (silicon substrate) made of the second material by anodizing.

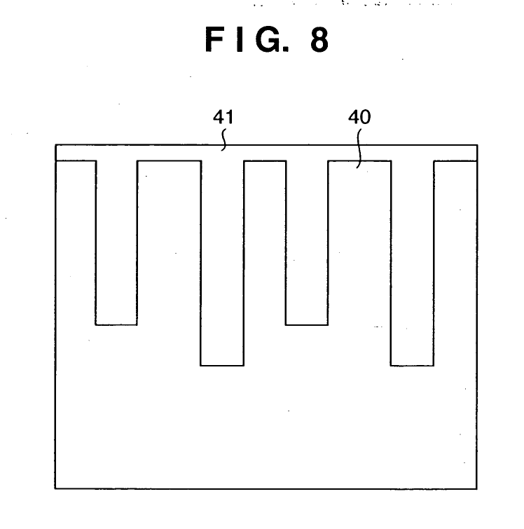

As the strain induction layer, a layer (Si₁₋ₓGeₓ layer) containing germanium is formed as the pore sealing material of the porous surface layer. A layer (preferably, a single-crystal silicon layer) almost made of silicon is formed on the Si₁₋ₓGeₓ layer as a strained semiconductor layer. FIG. 8 is a schematic sectional view showing a state in which the layer (Si₁₋ₓGeₓ layer) containing germanium is formed as the pore sealing member of a porous surface layer. As shown in FIG. 8, the pores in the surface layer of a porous layer 40 are filled with an Si₁₋ₓGeₓ layer 41 so that the Si surface is covered with the Si₁₋ₓGeₓ layer 41.

In the strain induction Si₁₋ₓGeₓ layer, x preferably falls within the range of 0 to 0.5. The Si₁₋ₓGeₓ layer is formed to fill the pores in the porous surface layer. Lattice relaxation occurs at least on the uppermost surface so that the strain there is small.

When the separation layer is a porous layer, the separation step is executed by wedge insertion, tensile/shearing force application, liquid jet (e.g-, water jet) injection, gas jet injection, or ultrasonic wave application.

The Si₁₋ₓGeₓ layer on the strained semiconductor layer is removed by polishing or chemical etching.

After the Si₁₋ₓGeₓ layer is removed, and only the strained semiconductor layer is left on the second substrate, surface planarization may be done. A manufacturing method according to this embodiment can further comprise a step of forming a circuit element by using the strained semiconductor layer as an active layer. For a device having such a circuit element, a high-speed operation can be implemented by the strained semiconductor layer.

### Fourth Embodiment

A layer (Si_{1-y}Ge_{y} layer) containing germanium is formed on the surface of a semiconductor substrate made of a second material. After that, a porous SiGe layer is formed by anodizing as a separation layer. A layer (Si₁₋ₓGeₓ layer) containing germanium is formed again as a strain induction layer on the porous SiGe layer. A layer (preferably, a single-crystal silicon layer) almost made of silicon is formed on the Si₁₋ₓGeₓ layer as a strained semiconductor layer made of a first material, thereby preparing a first substrate.

A second substrate made of a first material is bonded to the first substrate. The members are separated at the separation layer. After that, the remaining separation layer and SiGe layer are removed. Accordingly, the strained semiconductor layer made of the first material can be formed on the second substrate made of the first material while being in contact with the second substrate.

As the first and second materials, silicon is typically used.

In the Si₁₋ₓGeₓ layer as a strain induction layer, x preferably falls within the range of 0.1 to 0.5. More preferably, x is almost 0 on the surface of the semiconductor substrate and gradually changes. On the uppermost surface, x is preferably 0.1 to 0.5. Lattice relaxation occurs at least on the uppermost surface so that the strain there is small.

When the separation layer is a porous layer, the separation step is executed by wedge insertion, tensile/shearing force application, liquid jet (e.g., water jet) injection, gas jet injection, or ultrasonic wave application.

The Si₁₋ₓGeₓ layer on the strained semiconductor layer is removed by polishing or chemical etching.

After the Si₁₋ₓGeₓ layer is removed, and only the strained semiconductor layer is left on the second substrate, surface planarization may be done.

A manufacturing method according to this embodiment can further comprise a step of forming a circuit element by using the strained silicon layer as an active layer. For a device having such a circuit element, a high-speed operation can be implemented by the strained semiconductor layer.

### Fifth Embodiment

A layer (Si₁₋ₓGeₓ layer) containing germanium is formed as a strain induction layer on the surface of a semiconductor substrate made of a second material. After that, a porous SiGe layer is formed by anodizing as a separation layer. In the strain induction Si₁₋ₓGeₓ layer formed on the semiconductor substrate made of the second material, x preferably falls within the range of 0.1 to 0.5. More preferably, x is almost 0 on the surface of the semiconductor substrate and gradually changes. On the uppermost surface, x is preferably 0.1 to 0.5. Lattice relaxation occurs at least on the uppermost surface so that the strain there is small. Hence, the Si₁₋ₓGeₓ layer functions almost as a strain induction layer even after porosified.

A layer (preferably, a single-crystal silicon layer) almost made of silicon is formed on the Si₁₋ₓGeₓ layer as a strained semiconductor layer made of a first material, thereby preparing a first substrate.

A second substrate made of a first material is bonded to the first substrate. The members are separated at the separation layer. After that, the remaining separation layer and Si₁₋ₓGeₓ layer are removed. Accordingly, the strained semiconductor layer made of the first material can be formed on the second substrate made of the first material while being ink contact with the second substrate.

As the first and second materials, silicon is typically used.

When the separation layer is a porous layer, the separation step is executed by wedge insertion, tensile/shearing force application, liquid jet (e.g., water jet) injection, gas jet injection, or ultrasonic wave application.

The Si₁₋ₓGeₓ layer on the strained semiconductor layer is removed by polishing or chemical etching.

After the Si₁₋ₓGeₓ layer is removed, and only the strained semiconductor layer is left on the second substrate, surface planarization may be done.

A manufacturing method according to this embodiment can further comprise a step of forming a circuit element by using the strained silicon layer as an active layer. For a device having such a circuit element, a high-speed operation can be implemented by the strained semiconductor layer.

The examples of the present invention will be described below with reference to the accompanying drawings. Examples 1 to 5 to be described later correspond to the above-described first to fifth embodiments, respectively.

### EXAMPLE 1

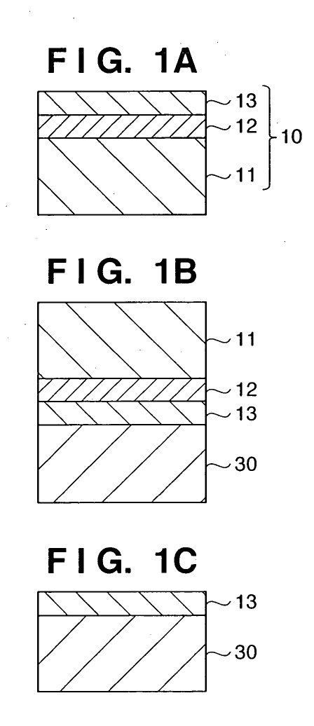

A method of manufacturing a semiconductor substrate (member) according to Example 1 of the present invention will be described with reference to FIGS. 1A to 1C.

In the step (lamination step) shown in FIG. 1A, a first substrate (member) 10 which has, on a silicon substrate 11, a layer (SiGe layer) 12 containing silicon and germanium (additional material), and a silicon layer 13 on the SiGe layer 12 is prepared.

[Epitaxial Growth of SiGe Layer]

First, the strain induction Si₁₋ₓGeₓ layer 12 (x=0.1 to 0.5 and, for example, x=0.3) is epitaxially grown on the silicon substrate 11 by CVD by lamp heating. The conditions are preferably as follows. Note that prebaking may be executed before growth.

Carrier Gas: H₂

The flow rate of H₂ is preferably 25 to 45 l/min and, typically, 30 l/min.

First Source Gas: SiH₄

The flow rate of SiH₄ is preferably 50 to 200 sccm and, typically, 100 sccm.

Second Source Gas: 2% GeH₄

The flow rate of 2% GeH₄ is preferably 20 to 500 sccm and, typically, 300 sccm.

Chamber Pressure

The chamber pressure is preferably 10 to 100 Torr and, typically, 100 Torr.

Temperature (Substrate Temperature)

The temperature is preferably 650° C. to 680° C.

Growth Rate

The growth rate is preferably 10 to 50 nm/min.

The composition ratio of Ge can be changed depending on the mixture ratio of the source gases. Preferably, the Ge concentration is set low at the early stage of growth on the single-crystal silicon substrate and increased as the epitaxial growth progresses. The Ge ratio is preferably finally set to x=0.1 to 0.5. The strain on the uppermost surface is relaxed by, e.g., introducing defects.

It is also preferable to anneal (prebake) the surface of the silicon substrate 11 in a hydrogen atmosphere before growth of the Si₁₋ₓGeₓ layer 12. In prebaking, the flow rate of hydrogen is preferably 15 to 45 l/min (typically 40 l/min). The temperature is preferably 700° C. to 1,000° C. (typically 950° C.). The chamber pressure is preferably 10 to 760 Torr (typically 80 Torr). At the early stage, the single-crystal silicon layer is preferably grown at a low growth rate of 50 nm/min or less.

When a sample is loaded/unloaded in/from the CVD apparatus, a native oxide film formed on the surface may be removed by, e.g., dipping the surface in a diluted HF solution in each step before loading in the apparatus.

[Formation of Strained-Si Layer]

Next, the single-crystal silicon layer 13 is grown on the Si₁₋ₓGeₓ layer 12 by CVD. The single-crystal silicon layer 13 formed in this way has a lattice constant different from that of the underlying Si₁₋ₓGeₓ layer 12 and therefore functions as a strained silicon layer. According to this example, the concentration of germanium in the Si₁₋ₓGeₓ layer 12 near the interface between the strained silicon layer 13 and the Si₁₋ₓGeₓ layer 12 can precisely be controlled. In addition, the concentration distribution in the interface can be made uniform (flat). Hence, the strain of the strained silicon layer formed on the Si₁₋ₓGeₓ layer 12 can easily be controlled. For this reason, a high-quality strained silicon layer 13 can be obtained. The growth conditions of the single-crystal silicon layer serving as the strained silicon layer 13 are as follows.

Carrier Gas: H₂

The flow rate of hydrogen is preferably 15 to 45 l/min and, typically, 30 l/min.

Source Gas: SiH₄

The flow rate of the source gas is preferably 50 to 500 SCCM and, typically, 100 SCCM.

Chamber Pressure

The chamber pressure is preferably 10 to 100 Torr and, typically, 80 Torr.

Growth Temperature (Substrate Temperature)

The growth temperature is preferably 650° C. to 1,000° C. and, typically, 900° C.

Growth Rate

The growth rate is preferably 10 to 500 nm/min.

[Finish on First Substrate Side]

With the above-described step, the first substrate (member) 10 schematically shown in FIG. 1A is obtained. Instead of forming the Si₁₋ₓGeₓ layer 12 and strained silicon layer 13 by multiple steps, as described above, the Si₁₋ₓGeₓ layer 12 and strained silicon layer 13 may be formed in a single step (e.g., the CVD step) by changing the Ge concentration (or the concentrations of other gases) and other conditions gradually or stepwise.

[Bonding]

Next to the step shown in FIG. 1A, in the step (bonding step) shown in FIG. 1B, a second substrate (member) 30 is bonded to the upper surface side of the first substrate (member) 10. The first substrate (member) 10 and second substrate (member) 30 may simply be bonded. Alternatively, to firmly couple the bonded substrates, anodizing or annealing may be executed. The second substrate (member) 30 is typically a silicon substrate. The bonding surfaces of the substrates to be bonded preferably undergo a hydrophobic treatment (this also applies to the examples to be described later). This is because if the bonding surfaces are hydrophilic, a silicon oxide film is formed at the bonding interface.

[Removal (Grinding/Etching) of Substrate]

Next to the step shown in FIG. 1B, in the step (removal step) shown in FIG. 1C, the silicon substrate 11 of the substrate (bonded substrate stack) formed by bonding is removed. The removal is done by, e.g., mechanical removal such as grinding or polishing or chemical removal such as wet etching or dry etching. If the substrate is removed by chemical etching, a solution mixture of KOH, K₂Cr₂O₇, propanol and H₂O is used. Si can be removed at a selectivity of about 20 times with respect to Si_{0.7}Ge_{0.3} (D. J. Godbey, et. al., Appl. Phys. Lett., vol. 56, no. 4, pp. 373-379 (1990)). Alternatively, when EDP (Ethylene Diamine Pyrocatechol) is used, Si can be removed at 82° C. at a selectivity of about 390 times with respect to Si_{0.72}Ge_{0.28} (D. Feijoo, et. al., J. Electro. Mat., vol. 23, no. 6, pp. 493-496 (1994)).

In addition, the Si₁₋ₓGeₓ layer 12 is removed. The Si₁₋ₓGeₓ layer 12 is to be removed by, e.g., polishing or chemical etching. If the Si₁₋ₓGeₓ layer 12 is removed by chemical etching, a solution mixture of HF (0.5%), HNO₃, and H₂O (5:40:20) is used. Si_{0.7}Ge_{0.3} can be removed at a selectivity of about 13 times with respect to Si (A. H. Krist, et. al., Appl. Phys. Lett., vol. 58, no. 17, pp. 1899-1901 (1991)).

That is, a transfer step is executed by the bonding step shown in FIG. 1B and the removal step shown in FIG. 1C. FIG. 1C is a schematic sectional view showing the semiconductor substrate manufactured by this example.

[Circuit by Strained-Si/H₂ Annealing]

When a circuit element is formed by using the strained silicon layer 13, a device with a high speed and low power consumption can be obtained. Formation of the circuit element (manufacture of a semiconductor device) will be described later. The surface may be planarized by polishing or hydrogen annealing as needed.

### EXAMPLE 2

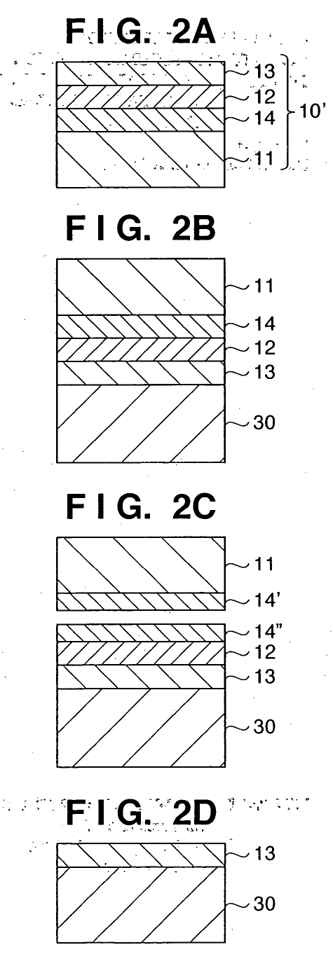

A method of manufacturing a semiconductor substrate (member) according to Example 2 of the present invention will be described with reference to FIGS. 2A to 2D. Before the Si₁₋ₓGeₓ layer of Example 1 is formed, a porous layer is formed near the surface of a silicon substrate 11 as a separation layer.

[Anodizing]

First, a porous Si layer 14 is formed on the single-crystal silicon substrate 11 by anodizing. Anodizing can typically be done by filling an anodizing tank having a platinum electrode pair with a solution containing hydrogen fluoride (HF), placing the silicon substrate 11 between the electrodes, and supplying a current between the electrodes.

The porous Si layer 14 formed by this step has a fragile structure and functions as a separation layer in the separation step later. For anodizing, the conditions-disclosed in, e.g., Japanese Patent Laid-Open No. 7-302889 can be employed.

A protective film such as an oxide film may be formed on the surfaces of internal pores of the porous Si layer 14. Alternatively, a plurality of layers having different porosities may be formed by controlling the anodizing solution or current. For example, a first porous layer may be formed on the surface side, and a second porous layer having a higher porosity than the first porous layer can be formed under the first porous layer.

[SiGe+Si EPI Bonding]

The steps of forming a strain induction Si₁₋ₓGeₓ layer 12 containing silicon and germanium (additional material) and a strained silicon layer 13 on the porous Si layer 14 and bonding the first substrate to the second substrate are the same as in Example 1. A first substrate (member) 10′ has a structure schematically shown in FIG. 2A. The structure shown in FIG. 2B is obtained by the bonding step.

It is also preferable to anneal (prebake) the surface of the porous Si layer 14 in a hydrogen atmosphere before the Si₁₋ₓGeₓ layer 12 is formed on the porous Si layer 14. In prebaking, the flow rate of hydrogen is preferably 15 to 45 l/min (typically 40 l/min). The temperature is preferably 700° C. to 1,000° C. (typically 950° C.). The chamber pressure is preferably 10 to 760 Torr (typically 80 Torr). At the early stage, the single-crystal silicon layer is preferably grown at a low growth rate of 50 nm/min or less.

When a sample is loaded/unloaded in/from the CVD apparatus, a native oxide film formed on the surface may be removed by, e.g., dipping the surface in a diluted HF solution in each step before loading in the apparatus.

[Removal (Separation/Etching) of Substrate]

Next to the step shown in FIG. 2B, in the step (separation step) shown in FIG. 2C, the substrate (bonded substrate stack) formed by bonding is separated into two substrates at the portion of the separation layer (porous Si layer) 14. That is, a transfer step is executed by the bonding step shown in FIG. 2B and the separation step shown in FIG. 2C. The separation step can be executed by, e.g., injecting a fluid to the separation layer 14 while rotating the bonded substrate stack about its axis. Reference numerals 14′ and 14″ schematically indicate porous layers remaining on the substrates after separation.

In place of the separation method using a fluid such as a liquid or gas, a separation method using stress of tension, compression, or shearing may be employed. Alternatively, these methods may be combined.

The porous layer 14″ which remains on the second substrate 30 after separation is removed by etching, polishing, grinding, or annealing in a reducing atmosphere containing hydrogen. To remove the porous layer by etching, the porous layer 14″ is selectively removed at a selectivity of about 1:10 by using a solution mixture of HF, H₂O₂, and H₂O.

When the large surface area of the porous layer is used, it can also selectively be removed by using another Si etchant.

In addition, the Si₁₋ₓGeₓ layer 12 is removed. The Si₁₋ₓGeₓ layer 12 is removed by, e.g., polishing or chemical etching. If the Si₁₋ₓGeₓ layer 12 is to be removed by chemical etching, a solution mixture of HF (0.5%), HNO₃, and H₂O (5:40:20) is used. Si_{0.7}Ge_{0.3} can be removed at a selectivity of about 13 times with respect to Si (A. H. Krist, et. al., Appl. Phys. Lett., vol. 58, no. 17, pp. 1899-1901 (1991)).

FIG. 2D is a schematic sectional view of the semiconductor substrate manufactured by this example.

[Circuit by Strained-Si/H₂ Annealing]

When a circuit element is formed by using the strained silicon layer 13, a device with a high speed and low power consumption can be obtained. Formation of the circuit element (manufacture of a semiconductor device) will be described later. The surface may be planarized by polishing or hydrogen annealing as needed.

### EXAMPLE 3

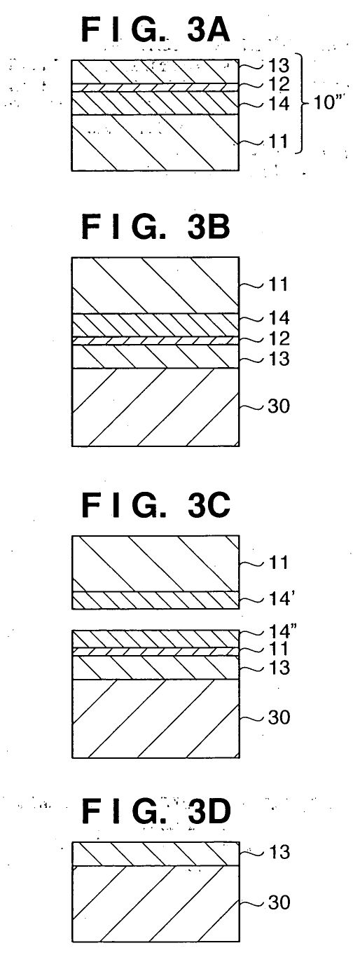

A method of manufacturing a semiconductor substrate (member) according to Example 3 of the present invention will be described with reference to FIGS. 3A to 3D. Instead of the Si₁₋ₓGeₓ formation step of Example 2, the pores of the porous layer are sealed by SiGe.

[Anodizing]

First, a porous Si layer 14 is formed on a single-crystal silicon substrate 11 by anodizing, as shown in FIG. 3A. Anodizing can typically be done by filling an anodizing tank having a platinum electrode pair with a solution containing hydrogen fluoride (HF), placing the silicon substrate 11 between the electrodes, and supplying a current between the electrodes. The porous Si layer 14 formed by this step has a fragile structure and functions as a separation layer in the separation step later. The conditions of anodizing are disclosed in, e.g., Japanese Patent Laid-Open No. 7-302889.

A protective film such as an oxide film may be formed on the surfaces of internal pores of the porous Si layer 14. Alternatively, a plurality of layers having different porosities may be formed by controlling the anodizing solution or current. For example, a first porous layer may be formed on the surface side, and a second porous layer having a higher porosity than the first porous layer can be formed under the first porous layer.

[Pore Sealing by SiGe]

The surface pores of the porous Si layer 14 are sealed by Si₁₋ₓGeₓ. The conditions are preferably as follows. Note that prebaking (to be described later) may be executed before growth.

Carrier Gas: H₂

The flow rate of H₂ is preferably 25 to 45 l/min and, typically, 30 l/min.

First Source Gas: SiH₄

The flow rate of SiH₄ is preferably 50 to 200 sccm and, typically, 100 sccm.

Second Source Gas: 2% GeH₄

The flow rate of 2% GeH₄ is preferably 20 to 500 sccm and, typically, 300 sccm.

Chamber Pressure

The chamber pressure is preferably 10 to 100 Torr and, typically, 100 Torr.

Temperature

The temperature is preferably 650° C. to 680° C.

Growth Rate

The growth rate is preferably 5 to 20 nm/min.

The composition ratio of Ge of the sealing Si₁₋ₓGeₓ layer can be changed depending on the mixture ratio of the source gases. Preferably, x=0.1 to 0.5. The strain of the sealing layer is relaxed due to the presence of surface pores. With this step, the strain induction Si₁₋ₓGeₓ layer 12 is formed.

It is also preferable to anneal (prebake) the surface of the silicon substrate 11 in a hydrogen atmosphere before pore sealing. In prebaking, the flow rate of hydrogen is preferably 15 to 45 l/min (typically 40 l/min). The temperature is preferably 700° C. to 1,000° C. (typically 950° C.). The chamber pressure is preferably 10 to 760 Torr (typically 80 Torr).

When a sample is loaded/unloaded in/from the CVD apparatus, a native oxide film formed on the surface may be removed by, e.g., dipping the surface in a diluted HF solution in each step before loading in the apparatus.

[Si EPI to Finish]

The steps from the step of forming a silicon layer 13 on the SiGe sealing layer to the finish are the same as in Example 2. A first substrate (member) 10″ has the structure schematically shown in FIG. 3A. The structure shown in FIG. 3B is obtained by the bonding step. After separation, the substrate is separated into two parts, as shown in FIG. 3C, and a transfer step is executed.

FIG. 3D is a schematic sectional view of the semiconductor substrate manufactured by this example.

[Circuit by Strained-Si/H₂ Annealing]

When a circuit element is formed by using the strained silicon layer 13, a device with a high speed and low power consumption can be obtained. Formation of the circuit element (manufacture of a semiconductor device) will be described later. The surface may be planarized by polishing or hydrogen annealing as needed.

### EXAMPLE 4

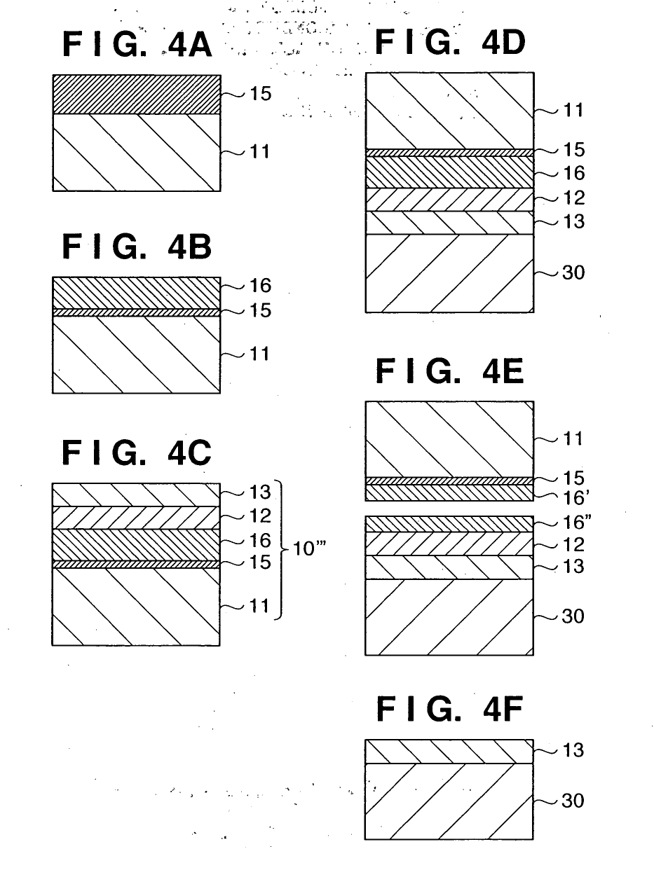

A method of manufacturing a semiconductor substrate (member) according to Example 4 of the present invention will be described with reference to FIGS. 4A to 4F. Instead of porosifying the silicon substrate of Example 2, a SiGe layer formed on a silicon substrate 11 is porosified.

[Epitaxial Growth of SiGe Layer]

As shown in FIG. 4A, a layer 15 (Si_{1-y}Ge_{y} layer: y=0.1 to 0.5 and, for example, y=0.3) containing silicon and germanium (additional material) is epitaxially grown on the single-crystal silicon substrate 11 by CVD by lamp heating. The conditions are preferably as follows. Note that the above-described prebaking may be executed before growth.

Carrier Gas: H₂

The flow rate of H₂ is preferably 25 to 45 l/min and, typically, 30 l/min.

First Source gas: SiH₄

The flow rate of SiH₄ is preferably 50 to 200 sccm and, typically, 100 sccm.

Second Source Gas: 2% GeH₄

The flow rate of 2% GeH₄ is preferably 20 to 500 sccm and, typically, 300 sccm.

Chamber Pressure

The chamber pressure is preferably 10 to 100 Torr and, typically, 100 Torr.

Temperature

The temperature is preferably 650° C. to 680° C.

Growth Rate

The growth rate is preferably 10 to 50 nm/min.

The composition ratio of Ge can be changed depending on the mixture ratio of the source gases. Preferably, the Ge concentration is set low at the early stage of growth on the single-crystal silicon substrate 11 and increased as the epitaxial growth progresses. The Ge ratio is preferably finally set to x=0.1 to 0.5. The strain on the uppermost surface is relaxed by, e.g., introducing defects.

[SiGe Anodizing]

Next to the step shown in FIG. 4A, in the step (anodizing step) shown in FIG. 4B, a porous layer 16 is formed on the Si_{1-y}Ge_{y} layer 15 by anodizing. Anodizing can typically be done by filling an anodizing tank having a platinum electrode pair with a solution containing hydrogen fluoride (HF), placing the silicon substrate 11 having the Si_{1-y}Ge_{y} layer 15 between the electrodes, and supplying a current between the electrodes. The porous layer 16 formed by this step has a fragile structure and functions as a separation layer in the separation step later.

A protective film such as an oxide film may be formed on the surfaces of internal pores of the porous layer. When SiGe is oxidized, SiO₂ is formed on the surface, and Ge is pushed inward. An oxide film is formed on the surfaces of the internal pores. Alternatively, a plurality of layers having different porosities may be formed by controlling the anodizing solution or current. For example, a first porous layer can be formed on the surface side of the Si_{1-y}Ge_{y} layer 15, and a second porous layer having a higher porosity than the first porous layer can be formed under the first porous layer. The porous layer 16 may be deeper than the Si_{1-y}Ge_{y} layer 15 and reach the silicon substrate 11 (FIG. 4B shows the porous layer 16 which does not reach the silicon substrate 11).

Since porous layer formation by anodizing is a kind of electrolytic etching, it is easy to selectively etch defects. Hence, the defects which are introduced in forming the Si_{1-y}Geₓ layer 15 hardly remain in the single-crystal silicon portion remaining after porous layer formation. As a result, the crystallinity recovers.

[SiGe+Si EPI to Finish]

The steps from the step of forming a strain induction layer (Si₁₋ₓGeₓ layer) 12 containing silicon and germanium (additional material) on the porous layer 16 to the finish are the same as in Example 2. A first substrate (member) 10″ has the structure schematically shown in FIG. 4C. The structure shown in FIG. 4D is obtained by the bonding step. After separation, the substrate is separated into two parts, as shown in FIG. 4E, and a transfer step is executed. FIG. 4F is a schematic sectional view of the semiconductor substrate manufactured by this example.

[Circuit by Strained-Si/H₂ Annealing]

When a circuit element is formed by using the strained silicon layer 13, a device with a high speed and low power consumption can be obtained. Formation of the circuit element (manufacture of a semiconductor device) will be described later. The surface may be planarized by polishing or hydrogen annealing as needed.

### EXAMPLE 5

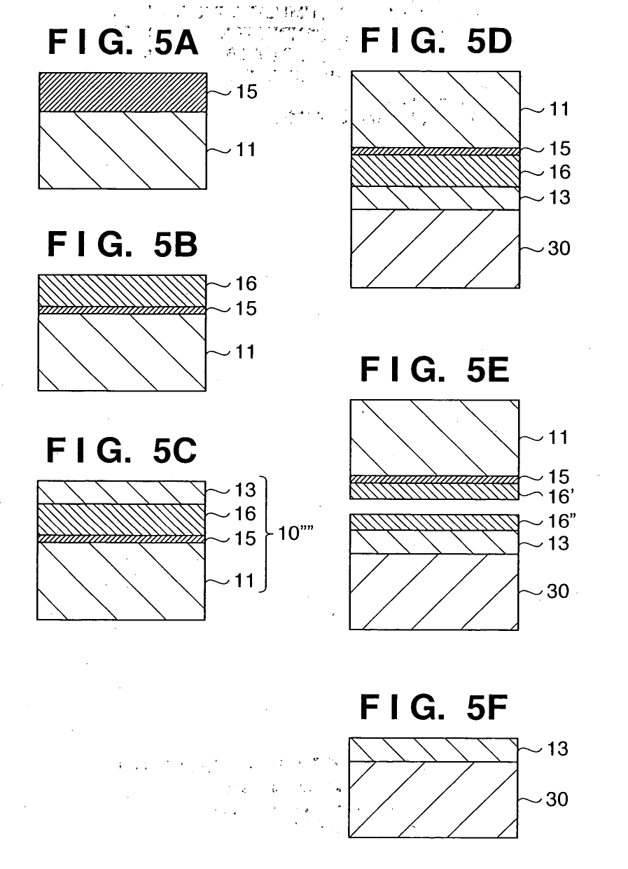

A method of manufacturing a semiconductor substrate (member) according to Example 5 of the present invention will be described with reference to FIGS. 5A to 5F. If lattice relaxation has already occurred on the surface of the porous SiGe layer of Example 4, a strained silicon layer 13 can be formed on it without forming another SiGe layer.

The remaining steps are the same as in Example 4. FIG. 5A is a schematic sectional view of the SiGe layer EPI step. FIG. 5B is a schematic sectional view of the anodizing step.

A first substrate (member) 10″ has the structure schematically shown in FIG. 5C. The structure shown in FIG. 5D is obtained by the bonding step. After separation, the substrate is separated into two parts, as shown in FIG. 5E, and a transfer step is executed. FIG. 5F is a schematic sectional view of the semiconductor substrate manufactured by this example.

[Circuit by Strained-Si/H₂ Annealing]

When a circuit element is formed by using the strained silicon layer 13, a device with a high speed and low power consumption can be obtained. Formation of the circuit element (manufacture of a semiconductor device) will be described later. The surface may be planarized by polishing or hydrogen annealing as needed.

### EXAMPLE 6

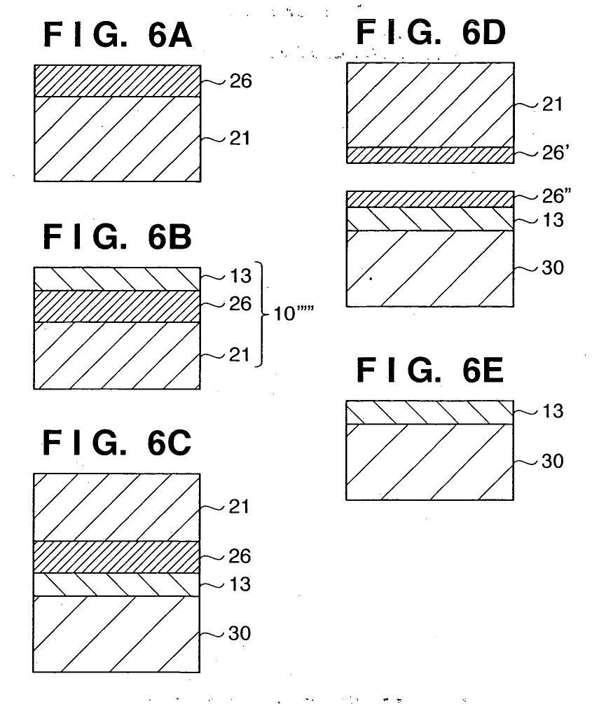

A method of manufacturing a semiconductor substrate (member) according to Example 6 of the present invention will be described with reference to FIGS. 6A to 6E.

Semiconductor Substrate

As a semiconductor substrate made of the second material of Examples 4 and 5, a substrate made of a material such as germanium having a lattice constant larger than that of silicon is used in place of a silicon substrate. In addition to germanium, a compound semiconductor such as SiGe or GaAs as a IV mixed crystal can be used. For SiGe bulk crystal, the Institute for Materials Research of Tohoku University has reported the growth of single-crystal bulk SiGe in the abstract of a new research project in the grants-in-aid for scientific research (S).

A porous layer 26 is formed on an SiGe or Ge substrate 21 (FIG. 6A). Since the crystal is a bulk crystal from the beginning, the lattice is aligned to the substrate. A strained-Si layer 13 is grown on the porous layer 26 (FIG. 6B). The structure is bonded to a second substrate (member) 30 (FIG. 6C). After that, the members are separated at a porous layer 24 (FIG. 6D). As in the above-described examples, the separation layer is removed so that a strained semiconductor substrate having the strained-Si layer 13 on the second substrate (member) 30 is manufactured (FIG. 6E).

Before formation of the porous layer 24, an Si₁₋ₓGeₓ layer may be formed to decrease the different in lattice constant to Si.

[Circuit by Strained-Si/H₂ Annealing]

When a circuit element is formed by using the strained silicon layer 13, a device with a high speed and low power consumption can be obtained. Formation of the circuit element (manufacture of a semiconductor device) will be described later. The surface may be planarized by polishing or hydrogen annealing as needed.

In the above-described examples, a strained semiconductor layer is formed by using, for a strain induction layer, a material having a lattice constant larger than that of a single-crystal semiconductor. The present invention can also be applied to a case in which a strained semiconductor layer is formed by using, for a strain induction layer, a material having a lattice constant smaller than that of a single-crystal semiconductor. For example, to form a strained semiconductor layer of silicon having a lattice constant smaller than that of single-crystal silicon, SiC or diamond may be used for the strain induction layer.

In the above-described examples, the strained semiconductor layer of silicon is formed directly on the silicon substrate as the second substrate. However, a noncrystal layer such as a layer of polysilicon (including microcrystalline silicon) or amorphous silicon may be formed on the strained semiconductor layer or second substrate and bonded so that the strained semiconductor layer is formed on the polysilicon layer or amorphous silicon layer (the amorphous silicon layer is changed to a polycrystal if annealing is to be executed to firmly couple the bonded substrates) formed on the silicon substrate. The semiconductor substrate manufacturing method of the present invention also incorporates this form. The structure having a polysilicon layer or the like formed on the silicon substrate is also incorporated as the “semiconductor substrate” of the present invention. The semiconductor substrate need not always be a single-crystal substrate. A polycrystal substrate may be used.

The semiconductor substrate serving as the second substrate may have a heavily doped impurity layer formed on its surface. Alternatively, the substrate itself may contain an impurity at a high concentration. For example, when a P⁺-substrate or a substrate having a P⁺-layer is used as the semiconductor substrate serving as the second substrate, and a strained semiconductor layer as a P⁻-layer is bonded to the substrate, a P⁻/P⁺-substrate can be manufactured.

<Example of Semiconductor Device>

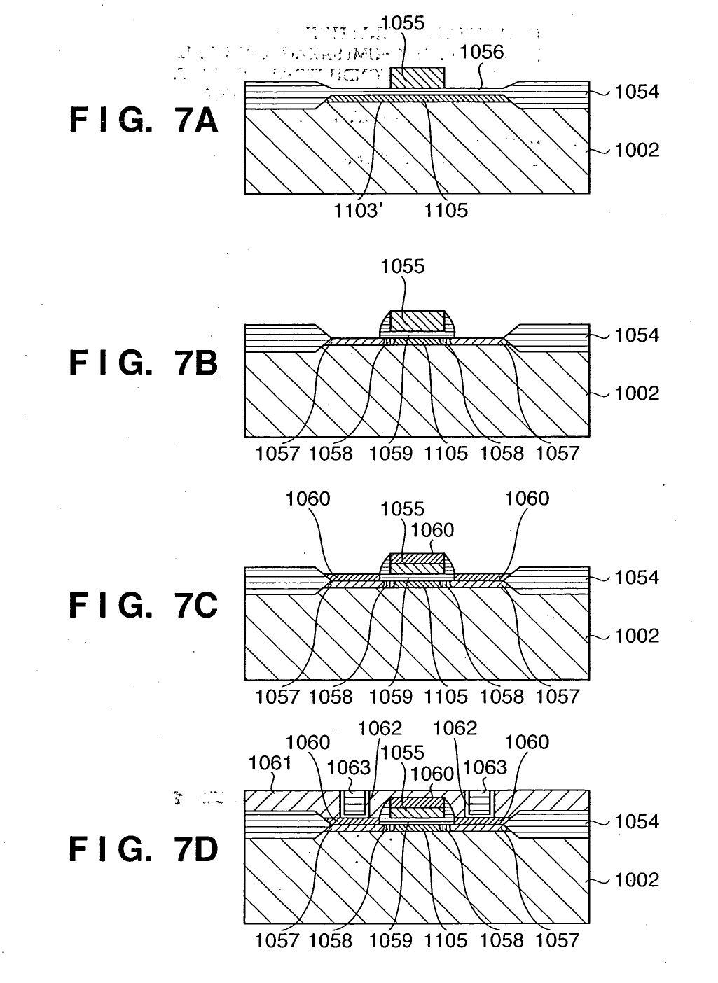

A semiconductor device (device) using a semiconductor substrate manufactured by the substrate manufacturing method described in the above examples and a manufacturing method thereof will be described next with reference to FIGS. 7A to 7D.

First, a semiconductor substrate is manufactured by using the semiconductor substrate (member) manufacturing method as Examples 1 to 5. This semiconductor substrate has a strained-Si layer on a silicon substrate, as described above. The semiconductor substrate will be referred to as a strained-Si substrate hereinafter. With such a strained-Si substrate, a device with a higher speed can be obtained as compared to a normal Si substrate. This is because the strained-Si layer is superior to an Si layer without strain.

In the step shown in FIG. 7A, an active region 1103′ in which a transistor (e.g., a field effect transistor such as a MOS transistor or a bipolar transistor) is to be formed and an element isolation region 1054 are formed on a prepared strained-Si substrate 1002. More specifically, the active region 1103′ and element isolation region 1054 can be formed by, e.g., a method of pattering a strained-Si layer 1105 into an island shape, a LOCOS oxidation method, or a trench method.

A gate insulating film 1056 is formed on the surface of the strained-Si layer 1105. As the material of the gate insulating film 1056, for example, silicon oxide, silicon nitride, silicon oxynitride, aluminum oxide, tantalum oxide, hafnium oxide, titanium oxide, scandium oxide, yttrium oxide gadolinium oxide, lanthanum oxide, zirconium oxide, or mixture glass thereof can suitably be used. The gate insulating film 1056 can be formed by, e.g., oxidizing the surface of the strained-Si layer 1105 or depositing an insulating substance on the strained-Si layer 1105 by CVD or PVD.

A gate electrode 1055 is formed on the gate insulating film 1056. The gate electrode 1055 can be made of, e.g., polysilicon doped with a p- or n-type impurity, a metal such as tungsten, molybdenum, titanium, tantalum, aluminum, or copper or an alloy containing at least one of them, a metal silicide such as molybdenum silicide, tungsten silicide, or cobalt silicide, or a metal nitride such as titanium nitride, tungsten nitride, or tantalum nitride. The gate insulating film 1056 may be formed by forming a plurality of layers made of different materials, like a polycide gate. The gate electrode 1055 may be formed by, e.g., a method called salicide (self-aligned silicide), a method called a damascene gate process, or any other method. With the above-described step, the structure shown in FIG. 7A is obtained.

In the step shown in FIG. 7B, an n-type impurity such as phosphorus, arsenic, or antimony or a p-type impurity such as boron is introduced into the active region 1103′ to form relatively lightly doped source and drain regions 1058. The impurity can be introduced by, e.g., ion implantation and annealing.

An insulating film is formed to cover the gate electrode 1055 and etched back to form a sidewall 1059 on the side portion of the gate electrode 1055.

An impurity of the same conductivity type as the above-described impurity is introduced into the active region 1103′ to form relatively heavily doped source and drain regions 1057. With the above-described step, the structure shown in FIG. 7B is obtained.

In the step shown in FIG. 7C, a metal silicide layer 1060 is formed on the upper surface of the gate electrode 1055 and the upper surfaces of the source and drain regions 1057. As the material of the metal silicide layer 1060, e.g., nickel silicide, titanium silicide, cobalt silicide, molybdenum silicide, or tungsten silicide can suitably be used. These silicides can be formed by depositing a metal to cover the upper surface of the gate electrode 1055 and the upper surfaces of the source and drain regions 1057, executing annealing to cause the metal and underlying silicon to react with each other, and removing an unreacted portion of the metal by an etchant such as sulfuric acid. The surface of the silicide layer may be nitrided as needed. With the above-described step, the structure shown in FIG. 7C is obtained.

In the step shown in FIG. 7D, an insulating film 1061 is formed to cover the upper surface of the gate electrode converted into a silicide and the upper surfaces of the source and drain regions. As the material of the insulating film 1061, silicon oxide containing phosphorus and/or boron can suitably be used. Contact holes are formed in the insulating film 1061 by CMP, as needed. When photolithography using KrF excimer laser, ArF excimer laser, F₂ excimer laser, electron beam, or X-rays is used, a rectangular contact hole having a side shorter than 0.25 μm or a circular contact hole having a diameter smaller than 0.25 μm can be formed.

The contact holes are filled with a conductor. As a conductor filling method, suitably, after a film of a refractory metal or a nitride thereof is formed on the inner surface of the contact hole as a barrier metal 1062 as needed, a conductor 1063 such as a tungsten alloy, aluminum, aluminum alloy, copper, or copper alloy is deposited by CVD, PVD, or plating. A conductor deposited higher than the upper surface of the insulating film 1061 may be removed by etch back or CMP. Before the contact holes are filled with the conductor, the surface of the silicide in the source and drain regions exposed to the bottom portions of the contact holes may be nitrided. With the above-described step, a transistor such as an FET can be formed on the strained-Si layer so that a semiconductor device having a transistor having the structure shown in FIG. 7D is obtained.

To form a CMOS transistor, a p-type substrate is used as the strained-Si substrate, and an n-well is formed in the substrate in the PMOS region.

FIGS. 7A to 7D show only one transistor region. To obtain a semiconductor device which achieve a desired function, a number of transistors or other circuit elements may be formed on the strained-Si substrate, and interconnections therebetween may be formed.

The present invention is used for a semiconductor substrate to form a circuit element such as a transistor on a strained semiconductor layer, a manufacturing method of the semiconductor substrate, and a semiconductor device in which the circuit element is formed.

The present invention can provide, e.g., a new technique to form an Si wafer having a strained-Si layer. By the semiconductor substrate of the present invention, the channel mobility can be increased by the strain without changing the process developed by the convention Si-LSI technique.

As many apparently widely different embodiments of the present invention can be made without departing from the spirit and scope thereof, it is to be understood that the invention is not limited to the specific embodiments thereof except as defined in the claims.

### CLAIM OF PRIORITY

This application claims priority from Japanese Patent Application No. 2003-434019 filed on Dec. 26, 2003, which is hereby incorporated by reference herein.

1. A semiconductor substrate comprising, on the semiconductor substrate, a strained semiconductor layer which is made of the same material as the semiconductor substrate.

2. The semiconductor substrate according to claim 1, wherein the material of the semiconductor substrate and the strained semiconductor layer is silicon.

3. A semiconductor substrate manufacturing method, comprising:
a first step of forming a strained semiconductor layer which is made of a first material on a semiconductor substrate which is made of a second material at least whose surface functions as a strain induction material to prepare a first substrate;
a second step of bonding the strained semiconductor layer of the first substrate to a second substrate which is made of the first material; and
a third step of removing a member on a side of the first substrate except the strained semiconductor layer and leaving the strained semiconductor layer on the second substrate.

4. The semiconductor substrate manufacturing method according to claim 3, wherein the first material is silicon.

5. The semiconductor substrate manufacturing method according to claim 3, wherein the first material is silicon, and the second material is Si₁₋ₓGeₓ (0<x≦1).

6. The semiconductor substrate manufacturing method according to claim 3, wherein the semiconductor substrate is a substrate having a strain induction layer formed on a surface.

7. The semiconductor substrate manufacturing method according to claim 6, wherein the semiconductor substrate is a substrate obtained by forming the strain induction layer on a silicon substrate.

8. The semiconductor substrate manufacturing method according to claim 6, wherein a separation layer is formed under the strain induction layer.

9. The semiconductor substrate manufacturing method according to claim 6, wherein the strain induction layer also serves as a separation layer.

10. The semiconductor substrate manufacturing method according to claim 8, wherein removal of the member on the side of the first substrate in the third step comprises a step of separating a partial member on the side of the first substrate at the separation layer.

11. The semiconductor substrate manufacturing method according to claim 6, wherein the strain induction layer is essentially made of silicon and an additional material.

12. The semiconductor substrate manufacturing method according to claim 11, wherein the strain induction layer is essentially made of SiGe.

13. The semiconductor substrate manufacturing method according to claim 8, wherein the separation layer is essentially made of a porous material.

14. The semiconductor substrate manufacturing method according to claim 13, wherein the porous material is one of porous Si or porous SiGe.

15. The semiconductor substrate manufacturing method according to claim 9, wherein the strain induction layer which also serves as the separation layer is essentially made of porous SiGe.

16. The semiconductor substrate manufacturing method according to claim 10, wherein in the third step, the member on the side of the first substrate except the strain induction layer, which remains on a side of the second substrate, is removed after the separation step at the separation layer.

17. The semiconductor substrate manufacturing method according to claim 3, wherein the third step comprises a step of, after only the strain induction layer is left on the second substrate, planarizing a surface of the strain induction layer.

18. The semiconductor substrate manufacturing method according to claim 9, wherein the strain induction layer which also serves as the separation layer is a porous layer in which the strain induction material to seal at least surface pores is introduced.

19. A semiconductor substrate manufactured by a method of claim 3.

20. A semiconductor device having a transistor formed on a strain induction layer of a semiconductor substrate of claim 1.
